(19) United States
(12) Patent Application Publication
(10) Pub. No.: US 2010/0269755 A1
(43) Pub. Date: Oct. 28, 2010

(54) VAPOR DEPOSITION SOURCE AND APPARATUS FOR PRODUCING ORGANIC EL ELEMENT

(75) Inventor: Junichi NAGATA, Chigasaki-shi (JP)

Correspondence Address: KRATZ, QUINTOS & HANSON, LLP, 1420 K Street, N.W., 4th Floor, WASHINGTON, DC, 20005, US

(73) Assignee: ULVAC, INC., Chigasaki-shi (JP)

(21) Appl. No.: 12/768,229

(22) Filed: Apr. 27, 2010

Related U.S. Application Data
(63) Continuation of application No. PCT/JP2008/069416, filed on Oct. 27, 2008.

(30) Foreign Application Priority Data
Nov. 5, 2007 (JP) 2007-287111

(51) Int. Cl. C23C 16/448

(52) U.S. Cl. 118/726

(57) ABSTRACT

Heat controllability of an evaporating vessel of a vapor deposition source is improved. The vapor deposition source of the present invention includes the evaporating vessel where an organic material is arranged; and a heating wire is wound around an outer periphery of the vapor deposition source. The portion of the organic material, which contacts a side wall of the evaporating vessel, is arranged below a lower end of the heating wire, and a substrate is attached to a substrate holder. When activating an electric power supply to make the heating wire generate heat for heating the evaporating vessel, a vapor of the organic material is discharged into a vacuum chamber through holes directed upward to attach to the substrate and form a thin film. Since the heating wire is arranged up to the upper end of the evaporating vessel, its opening can be heated to the evaporation temperature or higher; and since the evaporating vessel is made of any kind of metallic material of copper, copper-berylium alloy, Ti or Ta and its side wall and bottom wall are formed from 0.3 mm or more to 0.7 mm or less thick, the heat capacity is small and the controllability is high.

This application is a continuation of International Application No. PCT/JP2008/069416, filed on Oct. 27, 2008, which claims priority to Japan Patent Application No. 2007-287111, filed on Nov. 5, 2007. The contents of the prior applications are herein incorporated by reference in their entireties.

### BACKGROUND OF THE INVENTION

The present invention generally relates to a vapor deposition source and an apparatus using this vapor deposition source.

Conventionally, for evaporating vessels (crucibles) of the vapor deposition apparatuses, vessels made of graphite have been used. Since the crucibles made of graphite need to have a certain thickness which makes the crucibles heavy, the heat capacity becomes large.

Therefore, the temperature responsiveness of the crucibles is poor; and thus, it was difficult to accurately control the temperature of a vapor deposition material inside the crucible. In addition, when an organic material is filled into the crucible as the vapor deposition material, the organic material may sink into the crucible, depending upon the kind of organic material that is used.

### SUMMARY OF THE INVENTION

The present invention has been accomplished to solve the above-explained problems, and its object is to provide a vapor deposition source which has a high temperature responsiveness, and where a vapor deposition material is difficult to sink into an evaporating vessel.

### MEASURES TO SOLVE THE PROBLEMS

In order to solve the above problems, an embodiment of the present invention is directed to a vapor deposition source, that has an annular heating unit; and an evaporating vessel, which is inserted into the heating unit and in which an organic material is to be disposed. Also in the embodiment of this invention, when the heating unit generates heat, the organic material is heated so that vapor of the organic material is discharged from the evaporating vessel, wherein the evaporating vessel is made of any kind of metallic materials of copper, a copper-berylium alloy, Ti, or Ta; and the thickness of a side wall and a bottom wall thereof are formed in a range of 0.3 mm or more to 0.7 mm or less. A lower portion of the evaporating vessel, which is below the lower end of the heating unit, is not covered by the heating unit; and the organic material is disposed in a position below the lower end of the heating unit in the evaporating vessel.

In the present embodiment directed to the vapor deposition source, a water-cooling shroud is disposed around the heating unit; and an outer circumferential surface of the heating unit is set to face an inner circumferential surface of the water-cooling shroud.

In the present embodiment directed to the vapor deposition source, the height of the upper end of the water-cooling shroud is set to be lower than the height of an opening of the evaporating vessel, and the height of the lower end of the water-cooling shroud is set to be the same as or lower than the height of the lower end of the heating unit.

In the present embodiment directed to the vapor deposition source, a lid member to cover an inner space of the evaporating vessel is provided, the lid member having a lid body and a through hole formed in the lid body, the lid body being disposed between the opening and a bottom face of the evaporating vessel inside the evaporating vessel. Also in the present embodiment when a vapor is released from the organic material inside the evaporating vessel, the vapor fills the inner space of the evaporating vessel to be discharged to an outer space of the evaporating vessel through the through hole.

The present embodiment may be directed to the vapor deposition source, wherein the lid body is located in a space surrounded by the heating unit.

The present embodiment may also be directed to the vapor deposition source, wherein the lid member has a suspension portion connected to the lid body; the suspension portion is placed on an edge portion of the opening of the evaporating vessel; and the lid body is suspended in the inner space of the evaporating vessel by the suspension portion.

An embodiment of the present invention may be directed to an apparatus for producing organic EL element which produces an organic EL element by forming an organic thin film on a surface of a substrate that has a vacuum chamber; and a vacuum deposition source disposed inside the vacuum chamber. The vacuum deposition source has an annular heating unit; and an evaporating vessel which is inserted into the heating unit and in which an organic material is to be disposed, wherein when the heating unit generates heat, the organic material is heated, so that a vapor of the organic material is discharged from the evaporating vessel. The evaporating vessel is made of any kind of metallic materials of copper, a copper-berylium alloy, Ti, or Ta; and the thickness of a side wall and a bottom wall thereof are formed within a range of 0.3 mm or more to 0.7 mm or less; a lower portion of the evaporating vessel which is below the lower end of the heating unit is not covered by the heating unit; and the organic material is disposed in a position below the lower end of the heating unit in the evaporating vessel.

In the present embodiment directed to the apparatus for producing the organic EL element, a water-cooling shroud is disposed around the heating unit, and an outer circumferential surface of the heating unit is set to face an inner circumferential surface of the water-cooling shroud.

The present embodiment may also be directed to the apparatus for producing organic EL element, wherein the height of the upper end of the water-cooling shroud is set to be lower than the height of an opening of the evaporating vessel, and the height of the lower end of the water-cooling shroud is set to be the same as or lower than the height of the lower end of the heating unit.

In the present embodiment directed to the apparatus for producing organic EL element, a lid member to cover an inner space of the evaporating vessel is provided, the lid member having a lid body and a through hole formed in the lid body, and the lid body being disposed between the opening and a bottom face of the evaporating vessel inside the evaporating vessel. Also in this embodiment, when a vapor is released from the organic material inside the evaporating vessel, the vapor fills the inner space of the evaporating vessel to be discharged to the outer space of the evaporating vessel through the through hole.

In the present embodiment directed to the apparatus for producing the organic EL element, the lid body is located in a space surrounded by the heating unit.

The present embodiment may also be directed to the apparatus for producing the organic EL element, wherein the lid member has a suspension portion connected to the lid body. The suspension portion is placed on an edge portion of the opening of the evaporating vessel; and the lid body is suspended in the inner space of the evaporating vessel by the suspension portion.

### EFFECTS OF THE INVENTION

Since the evaporating vessel has a high heat responsiveness, a start-up time from a start of heating to the release of vapor can be shortened. Further, since the temperature of the organic material can be accurately controlled, the organic material can be evaporated without being decomposed. When a heating unit is stopped, the release of the vapor terminates in a short time. Since the organic material is not deposited on a through hole, the speed of discharging the vapor is stabilized. Since the organic material does not sink into the evaporating vessel, a very expensive organic material can be efficiently used.

### BRIEF DESCRIPTION OF THE DRAWINGS

FIG. 1 is a schematic diagram for illustrating a sectional view of a vacuum deposition apparatus used in an embodiment of the present invention.

FIG. 2 is a schematic diagram for illustrating a sectional view of a vapor deposition source used in an embodiment of the present invention.

### DETAILED DESCRIPTION OF THE INVENTION

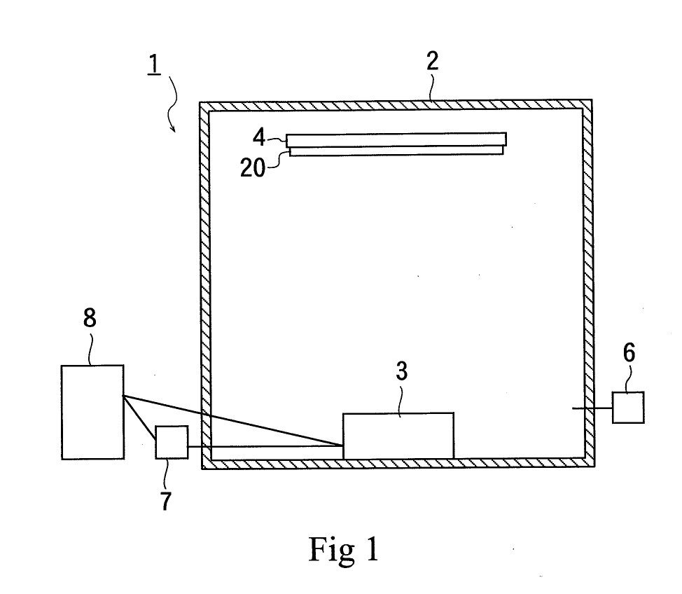

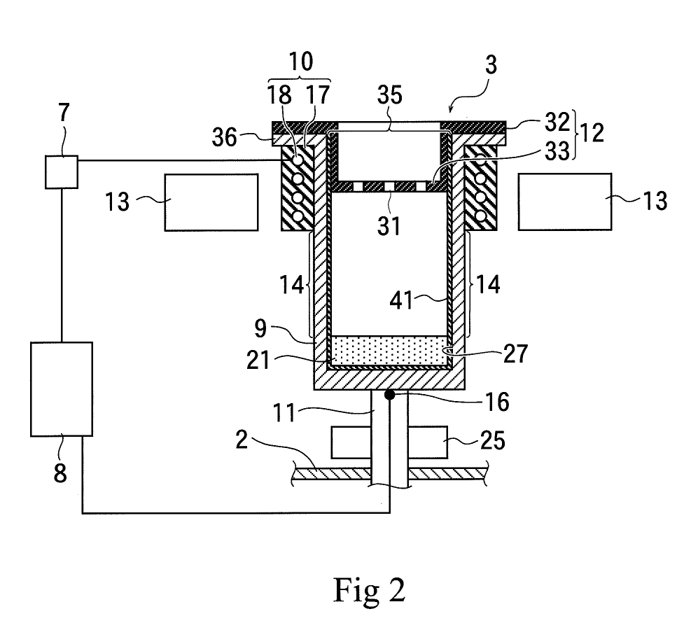

In FIG. 1, a reference numeral 1 generally shows one embodiment of the apparatus for producing the organic EL element (vacuum deposition apparatus) of the present invention. The vacuum deposition apparatus 1 has a vacuum chamber 2. A vapor deposition source 3 is arranged in a lower portion inside the vacuum chamber 2; and a substrate holder 4 is arranged above it. As shown in FIG. 2, the vapor deposition source 3 has an evaporating vessel 9, a heating unit 10 and a water-cooling shroud 13.

The heating unit 10 is annular, and has a uniform heat transmitter 17 annularly formed with a material having a high heat conductivity. The uniform heat transmitter 17 is arranged inside the vacuum chamber 2 such that its central axis is set almost vertically.

The evaporating vessel 9 is inserted vertically into the ring of the uniform heat transmitter 17 with an opening 35 directed upward (toward the ceiling side of the vacuum chamber 2), so that the uniform heat transmitter 17 is annularly attached around an outer circumferential face of the evaporating vessel 9.

The uniform heat transmitter 17 is internally provided with a heating wire 18, which is concentrically wound around the uniform heat transmitter 17, so that the evaporating vessel 9 is wound with the heating wire 18.

The length of the uniform heat transmitter 17 in the vertical direction (height direction) is set shorter than the length (height) of the evaporating vessel 9 in the vertical direction. A flange 36 (an edge portion of the opening 35) for reinforcement is formed at an upper end (around the opening 35) of the evaporating vessel 9, an upper end of the uniform heat transmitter 17 is in contact with the flange 36, and the flange 36 is put on the uniform heat transmitter 17. Therefore, the evaporating vessel 9 is suspended by the heating unit 10 in a state such that a bottom face portion is protruded from the heating unit 10. Specifically, the lower portion of the evaporating vessel 9, which is below the lower end of the uniform heat transmitter 17, is exposed to an inner atmosphere of the vacuum chamber 2 without being covered by the uniform heat transmitter 17.

A heating electric power supply 7 is arranged outside the vacuum chamber 2; and the heating wire 18 is connected to this heating electric power supply 7. When the heating wire 18 generates heat by passing electric current to the heating wire 18 with the heating electric power supply 7, a portion of the outer circumferencial side of the evaporating vessel 9, which is opposed to the uniform heat transmitter 17, is heated, and the temperature thereof is elevated through heat conduction from the uniform heat transmitter 17.

The evaporating vessel 9 is formed by drawing a copper sheet or a copper-berylium alloy sheet, and the thicknesses of a bottom face and a side wall are set within a range of 0.3 mm or more to 0.7 mm or less. Since the evaporating vessel 9 is thin, the weight of the crucible is small, and the heat capacity is low, so that the rates of rising and decreasing of the temperature are high, and the time lag in controlling the temperature is low.

An organic material 21 which is powdery is disposed, up to a position below the lower end of the uniform heat transmitter 17 inside the evaporating vessel 9; and a portion of the evaporating vessel 9 between the upper end of the organic material 21 and the lower end of the uniform heat transmitter 17 is an un-contacted portion 14 which contacts neither the uniform heat transmitter 17 nor the organic material 21; and through the un-contacted portion 14, the heat is conducted from its upper side to its lower side in order to heat the organic material 21, when the upper portion of the evaporating vessel 9 is heated by the heat conduction from the uniform heat transmitter 17.

Consequently, since the temperature of the upper portion of the lateral side of the evaporating vessel 9 on the upstream side of the heat becomes higher than the temperature of the lower portion on the downstream side of the heat, the temperature of a portion of the opening 35 of the evaporating vessel 9 in which the temperature is likely to decrease can be maintained at an evaporation temperature or higher, even if the temperature of the portion of the evaporating vessel 9 in which the organic material 21 is disposed has decreased to near the evaporating temperature.

A reaction preventing film 41 is formed on the bottom face and the inner circular face (exposing face 27) exposed to the inner space of the evaporating vessel 9. The reaction preventing film 41 is formed with, for example, nickel, a nickel-palladium alloy, platinum, rhodium, palladium or the like as a main component by a plating method.

The organic material 21 does not contact copper, but contacts the reaction preventing film 41 so that the organic material may not react with copper when the organic material 21 is heated to the evaporating temperature or higher.

The water-cooling shroud 13 is annular, and arranged such that it is concentric with the evaporating vessel 9 and the uniform heat transmitter 17 and surrounds the outer circumstance of the uniform heat transmitter 17. The water-cooling shroud 13 does not contact the uniform heat transmitter 17; and heat rays emitted from the outer circumferential side of the uniform heat transmitter 17 are shielded with the water-cooling shroud 13 so that a wall surface of the vacuum chamber 2 may not be heated.

The length of the water-cooling shroud 13 in the vertical direction is designed to be shorter than the length of the uniform heat transmitter 17 in the vertical direction; the lower end of the water-cooling shroud 13 is arranged at the same height as or lower than the lower end of the uniform heat transmitter 17; and the upper end of the water-cooling shroud 13 is located below the upper end of the uniform heat transmitter 17.

Therefore, the lower portion of the outer circumferential face of the uniform heat transmitter 17 faces the water-cooling shroud 13, while its upper portion does not face the water-cooling shroud 13, so that when cooling water is passed through the water-cooling shroud 13, the portion of the uniform heat transmitter 17 which faces the water-cooling shroud 13 is cooled by the water-cooling shroud 13, but the upper portion of the uniform heat transmitter which does not face the water-cooling shroud 13 is not cooled.

Consequently, the temperature of the portion of the opening 35 of the evaporating vessel 9 is prevented from decreasing so that the temperature of this portion may not descend below the evaporation temperature of the organic material 21, even when water is passed through the water-cooling shroud 13 for heating the evaporating vessel 9 with the uniform heat transmitter 17 through heat generation by applying current to the heater 18.

A lid member (crucible lid) 12 is arranged in the opening 35 of the evaporating vessel 9.

The lid member 12 has a lid body 33 which is in the shape of a plate and a suspension portion (suspending member) 32 which is in the shape of a ring attached to the lid body 33. The suspension portion 32 is placed on the edge (flange 36) of the opening 35 of the evaporating vessel 9; and the lid body 33 is suspended in the inner space of the evaporating vessel 9 by the suspension portion 32.

The suspension portion 32 closely contacts the periphery of the opening 35 of the evaporating vessel 9 with no space in between; and the opening 35 of the evaporating vessel 9 is covered with the lid member 12. Therefore, when vapor is released from the organic material 21 inside the evaporating vessel 9, the inner space of the evaporating vessel 9 is uniformly filled with the vapor of the organic material 21.

A plurality of through holes 31 are formed in the lid member 12. In this embodiment, the through holes 31 are formed in the lid body 33. The lid body 33 is arranged in the space between the bottom face and the opening 35 of the evaporating vessel 9 and is surrounded by the uniform heat transmitter 17. Accordingly, the lid member 12 is attached such that the through holes 31 are arranged inside the uniform heat transmitter 17.

As mentioned above, since the opening 35 of the evaporating vessel 9 is covered with the lid member 12 and the inner space of the evaporating vessel 9 is connected to the outer space of the evaporating vessel 9 only through the through holes 31, the vapor of the organic material 21 filled inside the evaporating vessel 9 is uniformly discharged inside the vacuum chamber 2 through the through holes 31.

In the following, steps of producing an organic EL element by forming an organic thin film on a surface of a substrate will be explained. A vacuum evacuation system 6 is connected to the vacuum chamber 2; a vacuum atmosphere is formed inside the vacuum chamber 2 by operating the vacuum evacuating system 6; and a substrate 20 is carried into the vacuum chamber 2, while the vacuum atmosphere is being maintained, to be attached to a substrate holder 4. FIG. 1 shows the substrate 20 in the state of being attached to the substrate holder 4.

The evaporating vessel 9 is supported vertically inside the vacuum chamber 2 by a supporting rod 11; and a temperature sensor 16 arranged inside the supporting rod 11 is attached to the bottom face of the evaporating vessel 9. The temperature sensor 16 is connected to a control unit 8 arranged outside the vacuum chamber 2.

In FIG. 2, a reference numeral 25 denotes a water-cooling shroud arranged under the bottom face of the evaporating vessel 9 so that the bottom wall of the vacuum chamber 2 may not be heated.

The temperature of the evaporating vessel 9 is detected by the temperature sensor 16; and the control unit 8 measures the temperature.

With cooling water passing through the water-cooling shrouds 13 and 25, heat is generated by applying current to the heating unit 10 while the temperature of the evaporating vessel 9 is being measured by the control unit 8 and the temperature sensor 16 in order to raise the temperature of the organic material 21 inside the evaporating vessel 9 to be heated to a temperature equal to or more than the evaporation temperature.

A heating temperature, which is a temperature equal to or more than the evaporation temperature of the organic material 21, is set in the control unit 8; and the temperature of the evaporating vessel 9 is maintained at the heating temperature by controlling the amount of the current to be applied to the heating unit 10 with the control unit 8.

The bottom face and the lateral face of the evaporating vessel 9 are thinner than an evaporating vessel made of carbon graphite; no reflection plate is arranged around the uniformly heating body 17; and the lateral face of the uniform heat transmitter 17 is exposed inside the vacuum chamber 2. Consequently, the heat capacity of the heating unit 10 and the evaporating vessel 9 is smaller than a heat capacity thereof when a reflection plate is arranged.

Consequently, when the current applied to the heating unit 10 is increased or decreased by the control unit 8, the temperature of the evaporating vessel 9 rapidly rises or falls, so that the temperature of the evaporating vessel 9 is maintained at the set heating temperature. As a result, since the organic material 21 is maintained at the temperature which is equal to or more than the evaporation temperature and less than the decomposition temperature, it can release the vapor without being heated to the decomposition temperature or higher.

In addition, as mentioned above, when the vapor is released from the organic material 21, the temperature of the portion of the opening 35 of the evaporating vessel 9 does not drop below the evaporation temperature. As discussed above, since the lid body 33 with the through holes 31 formed therein is located inside the uniform heat transmitter 17, and the lid member 12 is at a temperature equal to or more than the evaporation temperature, the vapor of the organic material 21 is not deposited on the portion of the opening 35 of the evaporating vessel 9 or the lid member 12, which prevents the diameter of the through hole 31 of the lid member 12 from changing.

The vapor of the organic material 21 discharged into the vacuum chamber 2 through the through holes 31 of the lid member 12 reaches a surface of the substrate 20 which faces the opening 35 of the evaporating vessel 9; and an organic thin film grows on the surface of the substrate 20.

When the application of the current to the heating wire 18 is stopped after the organic thin film is formed in a predetermined film thickness, the evaporating vessel 9 is rapidly cooled because the heat capacity of the heating unit 10 and the evaporating vessel 9 is small, so that the discharging of the vapor from the evaporating vessel 9 stops within a short time.

The substrate 20 with the organic thin film formed is carried out of the vacuum chamber 2, a substrate 20 without film having yet formed is carried into the vacuum chamber; and an organic thin film is formed in the same manner as described above.

In the above description, although the case where a water (cooling water) is used as a cooling medium for the water-cooling shrouds 13 and 25 has been explained, the present invention is not limited thereto. Other cooling medium (such as, an organic solvent, chlorofluorocarbon or the like) can be used.

Although the shape or the size of the evaporating vessel 9 is not particularly limited, it may, for example, be in the shape of a cylinder that has a bottom face in which the diameter of an opening 35 of the cylinder is from 25 mm or more to 65 mm or more and the height of the cylinder is 100 mm or more to 250 mm or less. In order to maintain the strength of the evaporating vessel 9, it is desirable to retain an edge portion (flange 36) in the form of a flange around the opening 35.

As to the material of the evaporating vessel 9 and the lid member 12, it is desirable to be an oxygen-free copper (C1020) in view of the heat conductivity and the specific heat. However, since the oxygen-free copper is soft, the strength of the evaporating vessel 9 and the lid member 12 is low, which requires careful handling.

When the usability of the evaporating vessel 9 and the lid member 12 is to be improved and also when a large evaporating vessel 9 and a large lid member 12 are to be made, tough pitch copper (C1100), phosphorous-deoxidized copper (C1201), berylium copper (C1700) or the like may be used. Although inferior to the oxygen-free copper, they have specific heats and heat conductivities relatively near thereto. Further, there is no problem in using a copper alloy as a substitute for the above-named ones, because it is more advantageous as compared to graphite. In summary, in the present invention, copper is suitable as a main component of the evaporating vessel 9 and the lid member 12. Meanwhile, besides copper, an evaporating vessel 9 and a lid member 12 composed mainly of other metal (such as Ta, Ti or the like) can also be used.

Various metals as named above can be used for the reaction preventing film 41, but a metal which contains either one or both of nickel and palladium is most desirable in terms of cost-efficiency.

The evaporating vessel made of graphite or stainless steel has a heat capacity of 32.95 J/K to 34.64 J/K, a heat conductivity of 16.3 W/m·K (made of stainless steel) or 104 W/m·K (graphite). On the other hand, the evaporating vessel 9 of the present application has a heat capacity of 8.40 J/K and a heat conductivity of 401 W/m·K; thus, it has a higher heat response as compared to the conventional evaporating vessel.

Like the evaporating vessel 9, the lid member 12 is also formed by drawing a copper sheet or a copper-berylium alloy sheet, while the thickness of at least the lid body 33 is made small (0.3 mm or more to 0.7 mm or less). When the thickness of the lid member 12 is made small, the weight of the entire vapor deposition source 3 is reduced. In addition, since the lid member 12 has a small heat capacity, the temperature rising rate and the temperature descending rate are high, which allows the time lag in controlling the temperature to became low.

What is claimed is:

1. A vapor deposition source, comprising:
an annular heating unit; and
an evaporating vessel which is inserted into the heating unit and in which an organic material is to be disposed, and when the heating unit generates heat, the organic material is heated so that a vapor of the organic material is discharged from the evaporating vessel,
wherein the evaporating vessel is made of any kind of metallic material of copper, a copper-berylium alloy, Ti, or Ta, and thickness of a side wall and a bottom wall thereof are formed in a range of 0.3 mm or more to 0.7 mm or less;
a lower portion of the evaporating vessel which is below the lower end of the heating unit is not covered by the heating unit; and
the organic material is disposed in a position below the lower end of the heating unit in the evaporating vessel.

2. The vapor deposition source as set forth in claim 1, wherein a water-cooling shroud is disposed around the heating unit, and an outer circumferential surface of the heating unit is set to face an inner circumferential surface of the water-cooling shroud.

3. The vapor deposition source as set forth in claim 2, wherein the height of the upper end of the water-cooling shroud is set to be lower than the height of an opening of the evaporating vessel, and the height of the lower end of the water-cooling shroud is set to be the same as or lower than the height of the lower end of the heating unit.

4. The vapor deposition source as set forth in claim 1, further comprising:
a lid member to cover an inner space of the evaporating vessel,
the lid member including a lid body and a through hole formed in the lid body,
the lid body disposed between the opening and a bottom face of the evaporating vessel inside the evaporating vessel,
wherein when a vapor is released from the organic material inside the evaporating vessel, the vapor fills the inner space of the evaporating vessel to be discharged to an outer space of the evaporating vessel through the through hole.

5. The vapor deposition source as set forth in claim 4, wherein the lid body is located in a space surrounded by the heating unit.

6. The vapor deposition source as set forth in claim 4, wherein the lid member comprises a suspension portion connected to the lid body, wherein the suspension portion is placed on an edge portion of the opening of the evaporating vessel, and wherein the lid body is suspended in the inner space of the evaporating vessel by the suspension portion.

7. An apparatus for producing organic EL element which produces an organic EL element by forming an organic thin film on a surface of a substrate, comprising:
a vacuum chamber; and
a vacuum deposition source disposed inside the vacuum chamber,
the vacuum deposition source including:
an annular heating unit, and
an evaporating vessel which is inserted into the heating unit and in which an organic material is to be disposed,
wherein when the heating unit generates heat, the organic material is heated, so that a vapor of the organic material is discharged from the evaporating vessel; and the evaporating vessel is made of any kind of metallic material of copper, a copper-berylium alloy, Ti, or Ta, and thickness of a side wall and a bottom wall thereof are formed within a range of 0.3 mm or more to 0.7 mm or less;
a lower portion of the evaporating vessel which is below the lower end of the heating unit is not covered by the heating unit; and
the organic material is disposed in a position below the lower end of the heating unit in the evaporating vessel.

8. The apparatus for producing the organic EL element as set forth in claim 7, wherein a water-cooling shroud is disposed around the heating unit, and wherein an outer circumferential surface of the heating unit is set to face an inner circumferential surface of the water-cooling shroud.

9. The apparatus for producing organic EL element as set forth in claim 8, wherein the height of the upper end of the water-cooling shroud is set to be lower than the height of an opening of the evaporating vessel, and wherein the height of the lower end of the water-cooling shroud is set to be the same as or lower than the height of the lower end of the heating unit.

10. The apparatus for producing organic EL element as set forth in claim 7, further comprising:
a lid member to cover an inner space of the evaporating vessel,
the lid member including a lid body and a through hole formed in the lid body,
the lid body being disposed between the opening and a bottom face of the evaporating vessel inside the evaporating vessel,
wherein when a vapor is released from the organic material inside the evaporating vessel, the vapor fills the inner space of the evaporating vessel to be discharged to the outer space of the evaporating vessel through the through hole.

11. The apparatus for producing the organic EL element as set forth in claim 10, wherein the lid body is located in a space surrounded by the heating unit.

12. The apparatus for producing the organic EL element as set forth in claim 10, wherein the lid member comprises a suspension portion connected to the lid body,
wherein the suspension portion is placed on an edge portion of the opening of the evaporating vessel, and
wherein the lid body is suspended in the inner space of the evaporating vessel by the suspension portion.
